(19) United States
(12) Patent Application Publication
(10) Pub. No.: US 2023/0226953 A1
(43) Pub. Date: Jul. 20, 2023

(54) METHOD FOR DISCHARGING A VEHICLE HIGH-VOLTAGE ELECTRICAL SYSTEM, ON-BOARD VEHICLE ELECTRICAL SYSTEM, AND INSULATION MONITORING DEVICES

(71) Applicant: Vitesco Technologies GmbH, Regensburg (DE)

(72) Inventor: Franz Pfeilschifter, München (DE)

(21) Appl. No.: 18/010,304

(22) PCT Filed: Jun. 14, 2021
(86) PCT No.: PCT/EP2021/065997

§ 371 Date: Dec. 14, 2022

(30) Foreign Application Priority Data
Jun. 26, 2020 (DE) 10 2020 207 972.2

(51) Int. Cl. B60L 58/40; G01R 31/00; G01R 31/52; B60L 3/00; B60L 53/62

(52) U.S. Cl. CPC B60L 58/40; G01R 31/006; G01R 31/52; B60L 3/0069; B60L 53/62

(57) ABSTRACT

A method for discharging a vehicle high-voltage electrical system, which is galvanically isolated from a ground potential, in the presence of a residual current makes provision for the following step: determining whether a residual current flows between a first HV potential of the vehicle high-voltage electrical system and the ground potential or a residual current flows between a second HV potential of the vehicle high-voltage electrical system and the ground potential. The method furthermore makes provision to discharge only that Cy capacitance which exists between the ground potential and that HV potential from which or to which the residual current flows. The discharging is triggered by determining the existence of a residual current. Furthermore, an on-board vehicle electrical system and an insulation monitoring device which are designed for performing the method are described. In addition, a corresponding charging-station high-voltage electrical system is described.

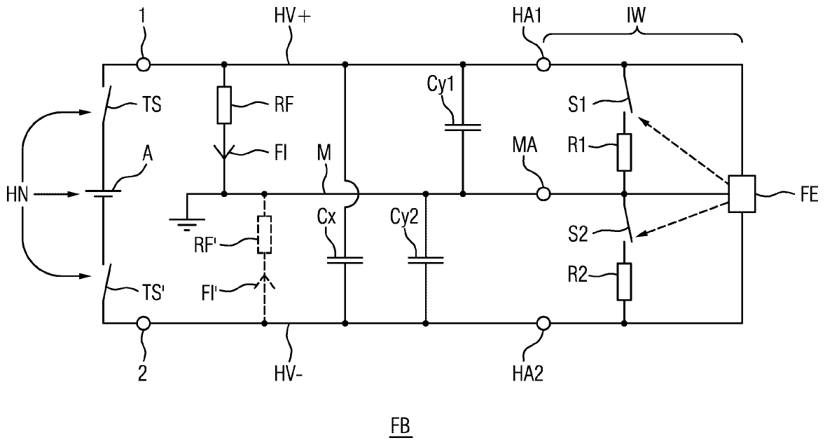

### CROSS REFERENCE TO RELATED APPLICATIONS

This application is the U.S. National Phase Application of PCT International Application No. PCT/EP2021/065997, filed Jun. 14, 2021, which claims priority to German Patent Application No. 10 2020 207 972.2, filed Jun. 26, 2020, the contents of such applications being incorporated by reference herein.

### BACKGROUND OF THE INVENTION

There exist electric vehicles which have a high-voltage electrical system which has a touch voltage that is dangerous for humans. To protect against an electric shock, use is made of residual current detection circuits which detect a residual current which results when a human touches a high-voltage potential.

It is known, as a measure when a residual current is detected, to disconnect the rechargeable battery and to discharge the capacitance between the high-voltage potentials (Cx capacitance). Since this capacitance comprises intermediate circuit capacitors, for example, and can amount to several mF, the duration for discharging such a capacitance is long.

### SUMMARY OF THE INVENTION

It is an aspect of the invention to demonstrate a way in which dangerous voltages, in particular in capacitances of vehicle high-voltage electrical systems, can be quickly reduced.

It has been recognized that the dangerous touch voltage, i.e. the residual current, can be quickly reduced if only the voltage between the critical (touched) high-voltage potential (for short: HV potential) and ground is reduced by discharging since this only requires the discharging of a Cy capacitance (namely that which exists between the critical high-voltage potential and ground). Since the magnitude of Cy capacitances is substantially composed of the parasitic capacitances and Cy filter capacitances, which usually amount to less than one μF, the discharging can be performed many times quicker than with protection mechanisms which require the voltage between the two HV potentials to be discharged. If a residual current which flows away from an HV potential or flows to an HV potential (“critical HV potential”) is detected, it can be assumed that this potential is being touched by a human. To decrease the risk of an electrical accident, provision is made to discharge this HV potential toward ground, wherein only the Cy capacitance between this potential and the ground potential (for short: ground) is to be discharged here. Provision is made, in this case, not to discharge the other potential toward ground, as a result of which the total energy to be transferred by discharging is reduced, for instance compared to the capacitance between the HV potentials being discharged. The result is a significantly shorter discharging duration, meaning that the risk posed by the HV potential, which is the cause of the residual current, i.e. the critical or touched potential, is significantly reduced.

A method for discharging a vehicle high-voltage electrical system, which is galvanically isolated from a ground potential, is thus described. The discharging is carried out if a residual current is present. Discharging refers in particular to the discharging of an HV potential of the vehicle high-voltage electrical system to ground. The HV potentials are in particular (negative and positive) HV supply potentials.

It is determined whether a residual current exists between a first HV potential (for instance a positive HV potential) of the vehicle high-voltage electrical system and the ground potential, or whether a residual current exists between a second HV potential (for instance a negative HV potential) of the vehicle high-voltage electrical system and the ground potential. This can be done by directly measuring the current, by deriving the residual current from other current measurements, or can be determined indirectly, for instance by monitoring a voltage between ground and one of the HV potentials and taking consideration of its magnitude or rate of change. The trigger for discharge is the determination that a residual current is present, in particular a residual current which is determined as outlined (or the presence of which is determined as outlined).

It is (if a residual current is present) discharged only that Cy capacitance which exists between the ground potential and the critical HV potential is discharged. In particular, only that Cy capacitance which exists between the ground potential and that HV potential from which or to which the residual current flows is discharged. Critical (or touched) potential refers to that HV potential from which or to which the residual current flows.

The discharging is triggered by determining the existence of a residual current. Discharging refers to a step of producing a discharging current. This discharging current corresponds to a charge which flows away (toward ground) from that Cy capacitance which is connected to the critical potential. This step ends, for example, after a certain period of time, preferably no more than 50 ms, 20 ms or 3 ms long. At the end of the discharging step, the voltage of the relevant Cy capacitance (i.e. the voltage between ground and the critical HV potential) amounts to less than a predefined proportion of the original voltage, for instance no more than 20%, 10% or 5% or 1%, or amounts to less than a predefined voltage limit, for instance 60 V, 40 V, 20 V or 10 V. The discharging step can be ended after a predefined period of time, for instance after 10 ms or 5 ms or 3 ms from the start of the discharging. The discharging of one Cy capacitance (the Cy capacitance connected to the critical HV potential) can coincide with the other Cy capacitance, i.e. the Cy capacitance between ground and the non-critical HV potential, being charged. Although this can lead to an increasing voltage between ground and the non-critical HV potential, the non-critical HV potential is also not touched or is not causally linked to the residual current. Non-critical HV potential refers to that one of the two HV potentials which does not correspond to the critical potential, i.e. which is not involved in the residual current flow.

Provision can be made for discharging of that Cy capacitance (the non-critical capacitance) which is connected between the ground potential and that HV potential which has no residual current flow to be prevented. Simultaneous discharging of the two HV potentials toward ground potential would mean discharging of the Cx capacitance (between the two HV potentials), wherein this would require a significantly longer period of time. Capturing the existence of the residual current triggers the discharging of the critical Cy capacitance, but not simultaneously discharging of the Cx capacitance. The discharging of the Cx capacitance can however be triggered or begun at a later time (for instance delayed by a predetermined period of time in relation to the discharging of the Cy capacitance). In particular, after discharging the Cy capacitance which is connected to the HV potential linked to the residual current flow, the other Cy capacitance can be discharged and/or the Cx capacitance can be discharged (delayed by a predetermined period of time).

Furthermore, after discharging the Cy capacitance which is connected to the HV potential linked to the residual current flow, a safety measure can be performed, for instance the disconnection of a high-voltage source of the vehicle high-voltage electrical system. In particular, a fault signal can be output when the existence of a residual current is captured. If the high-voltage source is not disconnected, there is still the possibility to continue the operation of the on-board high-voltage electrical system, for instance making (only) one journey (“limp home”). Provision can be made for the high-voltage source to be disconnected if the residual current occurs. Provision can be made for the high-voltage source to be re-connected to the HV potentials if the step of discharging the Cy capacitance has ended. The step of discharging the Cy capacitance can be ended if the discharging has been performed for a predefined minimum period of time (for instance 10 ms or 30 ms), or if the voltage across the Cy capacitance that is to be discharged lies below a predefined voltage limit, for instance 60 V, 40 V, 20 V or 10 V. This allows the high-voltage electrical system to be restarted, for instance in order to make one journey (“limp home”).

After discharging the Cy capacitance which is connected to the HV potential linked to the residual current flow, a Cx capacitance which exists between the first HV potential and the second HV potential can be discharged. The Cx capacitance can comprise one or more intermediate circuit capacitors and/or parasitic Cx capacitances. In particular, the Cx capacitance can be discharged if the discharging of the Cy capacitance has concluded, for instance if a predetermined period of time has elapsed or if the voltage between the critical potential and the ground potential lies below a predefined limit, for instance below 60 V, 40 V, 20 V or 10 V. A high-voltage source is preferably disconnected before the discharging of the Cx capacitance begins.

The determining of whether a residual current flows between a first HV potential of the vehicle high-voltage electrical system and the ground potential or a residual current flows between a second HV potential (HV−) of the vehicle high-voltage electrical system and the ground potential (M) can be carried out by means of direct or indirect residual current capture. To this end, an impedance across which the residual current flows can be determined. If this impedance lies in a predefined range, it can be assumed that the residual current is flowing through a human. This range can have a value of 300 Ohm, 400 Ohm, 600 Ohm or 1000 Ohm as the lower limit, for example. Furthermore, this range can have a value of 1200 Ohm, 1500 Ohm, 2000 Ohm or 2500 Ohm as the upper limit, for example. Provision can be made for the step of discharging the Cy capacitance to be carried out only if this impedance lies in the impedance range. The impedance range characterizes the impedance of a human body (between the critical HV potential and ground). Provision can be made for disconnection of a high-voltage source of the vehicle high-voltage electrical system and/or discharging of a Cx capacitance which exists between the first HV potential and the second HV potential to be prevented. This allows the vehicle high-voltage electrical system to be continued to be used after the touching has ended, for instance in order to make one (single) journey (“limp home”). Furthermore, a present charging process or feeding-back process with a charging station can be prevented, in particular independently of the impedance, if the presence of a residual current is determined.

The determining that a residual current is present (and at which potential) and optionally the determining of the magnitude of the residual current or of an impedance through which the residual current flows can be carried out in various ways. For example, the determining of whether a residual current flows between a first HV potential of the vehicle high-voltage electrical system and the ground potential or a residual current flows between a second HV potential of the vehicle high-voltage electrical system and the ground potential may comprise: measuring a rate of change of a voltage between ground and one of the HV potentials. Provision can be made here for it to be determined that a residual current exists if the absolute value of the rate of change lies above a limit which characterizes the maximum rate of change which occurs during an active insulation measurement. This avoids false alarms. Active insulation measurements provide a test current which is used to shift the HV potentials with respect to the ground potential in order to be able to extrapolate, from the rate of change, the insulation resistances of the HV potentials with respect to the ground potential. These test currents are however significantly smaller than the residual currents described here and are based on current conduction through a test resistor in the megaohm range. A maximum rate of change which occurs during an active insulation measurement can be, for example, 200 V, 400 V or 800 V based on a period of time of 1 s, 4 s or 8 s. The maximum rate of change preferably amounts to at least 25 V/s and/or no more than 800 V/s.

The discharging of the Cy capacitance can be provided by closing a discharging switch which is connected between the ground potential and the critical HV potential. The discharging switch can be connected to ground or to the critical HV potential here via one or more resistor components and/or via one or more varistors. The discharging switch can comprise a semiconductor switch, an optoelectronic relay or an electromechanical switch. The discharging switch can be provided upstream of one or more switching elements connected in series, in particular of one or more normally off switching elements. The two discharging switches, via which the two HV potentials are connected to the ground potential, can be driven for instance by XOR logic in order to avoid the two switches being switched on (conductive) simultaneously. The discharging switch(es) can be connected to ground via one or more varistors connected in series. The discharging switch(es) can be connected to the ground potential and to the relevant HV potential via one or more varistors and/or one or more resistor components. The varistors and/or resistors limit the current flow through the discharging switch and are preferably cod in such a way that a Cy capacitance of 100 nF is discharged from 800 V or 400 V to no more than 60 V, 40 V or 20 V within less than 50 ms or less than 30 ms. The breakdown voltage of the varistor or of the series circuit comprising the varistors amounts to no more than 60 V, 40 V or 20 V, for example. The switching elements, resistor components and/or varistors used for this purpose are designed for voltages of more than 1 kV, in particular of more than 2 kV. If a plurality of serial switching elements are used for realizing a discharging switch, this results in a redundancy which prevents unintentional discharging. The discharging switches are preferably normally off, i.e. not driven in the open state.

Furthermore, an insulation monitoring device of a vehicle high-voltage electrical system configured to perform the method described here is described. This vehicle high-voltage electrical system can have one or more physical features which are used for performing the method. The insulation monitoring device has a ground potential connection (for connection to the ground potential) and a first and a second HV potential connection (for connection to the first and second HV potential). The insulation monitoring device has a residual current detection means. This residual current detection means is designed to detect a first residual current, which flows between a first HV potential of the first HV potential connection and the ground potential of the ground potential connection, and a second residual current, which flows between a second HV potential of the second HV potential connection and the ground potential of the ground potential connection, preferably individually and in particular separably from one another.

The insulation monitoring device has a discharging circuit. The residual current detection means is connected to the discharging circuit such that it can drive the latter. The discharging circuit is configured to connect only the first HV potential connection to the ground potential connection in a controlled manner if the residual current detection means captures the first residual current. The discharging circuit is configured to connect only the second HV potential connection to the ground potential connection if the residual current detection means captures the second residual current. The discharging circuit can thus be configured in such a way that the residual current detection means is connected to it in such a way that the residual current detection means, the discharging circuit or both connect only one of the HV potentials to the ground potential.

The discharging circuit can have a first discharging switch between the first HV potential connection and the ground potential connection. The discharging circuit can furthermore have a second discharging switch between the second HV potential connection and the ground potential connection. The discharging switches are in particular configured to be closed only one at a time, and not simultaneously, in particular by virtue of these discharging switches being driven accordingly by the residual current detection means or a controller of the discharging circuit. The discharging switches can be configured and connected as outlined in the scope of the explanation of the method.

An on-board vehicle electrical system having an insulation monitoring device can be designed as described here. The on-board vehicle electrical system can have a ground potential (for instance chassis potential) and a vehicle high-voltage electrical system which is galvanically isolated from said ground potential. The vehicle high-voltage electrical system can have a first HV potential and a second HV potential. The first HV potential connection of the insulation monitoring device is connected to the first HV potential of the vehicle high-voltage electrical system. The second HV potential connection of the insulation monitoring device is connected to the second HV potential of the vehicle high-voltage electrical system. The ground potential connection of the insulation monitoring device is connected to the ground potential of the on-board vehicle electrical system. The on-board vehicle electrical system can furthermore have an energy store, for instance a high-voltage rechargeable battery, which is connected to the HV potentials, preferably via at least one disconnecting switch. The at least one disconnecting switch can be configured to be opened if the presence of a residual current is captured.

In addition, an insulation monitoring device of a charging-station high-voltage electrical system is described. As in the case of the described on-board vehicle high-voltage electrical system, this insulation monitoring device has a ground potential connection and a first and a second HV potential connection. The insulation monitoring device of the charging-station high-voltage electrical system furthermore has a residual current detection means which is designed to detect a first residual current between a first HV potential of the first HV potential connection and the ground potential of the ground potential connection, and a second residual current between a second HV potential of the second HV potential connection and the ground potential of the ground potential connection. This refers to the potentials and connections of the charging-station high-voltage electrical system. The charging-station high-voltage electrical system has a discharging circuit, wherein the residual current detection means is connected to the discharging circuit such that it can drive the latter, wherein the discharging circuit is configured to connect only the first HV potential connection to the ground potential connection in a controlled manner if the residual current detection means captures the first residual current, and to connect only the second HV potential connection to the ground potential connection if the residual current detection means captures the second residual current. These components and variables refer to the charging station. The charging-station high-voltage electrical system can also be referred to as charging station for short. Provision can be made for a charging station which has the insulation monitoring device of a charging-station high-voltage electrical system described here. The connections mentioned in this regard here are the connections of the charging station which are configured to deliver the charging power of the charging station, in particular via a plug connection or via a charging cable. The charging station preferably also comprises the charging-station high-voltage electrical system described.

The components and variables described with regard to the insulation monitoring device of the charging-station high-voltage electrical system are preferably designed like the relevant components/variables of the vehicle high-voltage electrical system described here, in particular since the same mechanisms and similar components to those in the vehicle high-voltage electrical system are used in the charging-station high-voltage electrical system.

One embodiment of the insulation monitoring device of the charging-station high-voltage electrical system makes provision for the discharging circuit to have a first (charging-station-side) discharging switch between the first HV potential connection and the ground potential connection, and to have a second (charging-station-side) discharging switch between the second HV potential connection and the ground potential connection. These discharging switches are configured to be closed only one at a time, and not simultaneously. The discharging switches are preferably part of the charging-station high-voltage electrical system, the charging station and/or the insulation monitoring device of the charging-station high-voltage electrical system.

### BRIEF DESCRIPTION OF THE DRAWINGS

The FIGURE serves to explain the methods and apparatuses described here.

### DETAILED DESCRIPTION OF THE PREFERRED EMBODIMENTS

The FIGURE shows an on-board vehicle electrical system FB having a vehicle high-voltage electrical system HN. The vehicle high-voltage electrical system has a first, positive HV potential HV+ and a second, negative HV potential HV−. All poles of the disconnecting switches TS, TS′, which separably connect a high-voltage rechargeable battery A of the vehicle high-voltage electrical system HN to the HV potentials HV+, HV−, are connected to rechargeable battery connections 1, 2 of the vehicle high-voltage electrical system HN. The on-board vehicle electrical system FB furthermore has a ground potential M. This potential M can be a negative supply potential of an on-board low-voltage electrical system (not illustrated). The potential M (and in particular the on-board low-voltage electrical system) are galvanically isolated from the vehicle high-voltage electrical system HN. The potential M is in particular the chassis potential of the vehicle in which the on-board vehicle electrical system FB is provided.

If a person touches the chassis (ground potential M), illustrated by the resistor RF, and there exists an insulation fault of the vehicle high-voltage electrical system HN in such a way that the chassis has a (high) voltage with respect to the ground potential M, a residual current FI flows through this person. In the illustrated case, a residual current FI flows from the first (i.e. positive) HV potential HV+ to the ground potential. The procedure described here makes provision, if the presence of a residual current FI is detected, for the HV potential HV+ to be shifted toward the ground potential by closing a switch S1. Since a Cy capacitance C1 exists between the HV potential HV+ and the ground potential (for instance realized by parasitic capacitances of the vehicle high-voltage electrical system HN or of the HV potential HV+ with respect to the ground potential M and an EMC filter capacitance between these potentials), this Cy capacitance is discharged when shifting the HV potential HV+ toward the ground potential M. This switch S1 is therefore referred to as discharging switch S1. This procedure is also provided for the second HV potential HV− if this second HV potential is connected to the ground potential M via a resistor RF′ (for instance the body resistance of a person), as a result of which a residual current FI′ arises.

So that only the relevant HV potentials touched by a person are brought to the level of the harmless ground potential M by discharging the relevant Cy capacitance, and no further, time-consuming discharging operations have to be carried out, the non-relevant Cy capacitance is not discharged toward ground potential M. If the residual current FI occurs at the HV potential HV+, the Cy capacitance Cy1 between M and HV+ is discharged by closing the discharging switch S1. The discharging switch S2, which is connected to the non-relevant potential HV−, is not closed in the event of such a fault (cf. RF) with respect to HV+. If the residual current FI′ occurs at the HV potential HV−, the Cy capacitance Cy1 between M and HV− is discharged by closing the discharging switch S2. The discharging switch S1, which is connected to the non-relevant potential HV+, is not closed in the event of such a fault (cf. RF′) with respect to HV−. The Cx capacitor Cx (for instance an intermediate circuit capacitor) between the HV potentials HV+ and HV− is not discharged via the discharging switches S1, S2.

The presence of a residual current (RF or RF′) is captured by the residual current detection means FE which is connected to the ground potential M and to the HV potentials HV+, HV− via the ground potential connection MA and via a first and a second HV potential connection HA1, 2. These connections and the residual current detection means FE are part of the insulation monitoring device IW. This insulation monitoring device furthermore comprises the discharging switches S1, S2 which are connected via current limiting resistors R1, R2 to ground M and to the HV potentials HV+, −, respectively. The discharging switch S1 is (directly) connected to the ground potential M via the resistor R1 and is connected to the HV potential HV+. The discharging switch S2 is connected to the HV potential HV+ via the resistor R2 and is (directly) connected to the ground potential M. Both switches can however be directly connected to the respective HV potential and via respective resistors R1, R2 to the ground potential. Varistors can be used instead of or in combination with the resistors R1, R2. The resistors and/or varistors can be provided by a plurality of series-connected resistor components or varistor components in order to realize a redundancy. The switches S1, S2 can also each be formed of a series circuit comprising a plurality of switching elements (in particular transistors such as MOSFETs). The result of this is a redundancy and lower maximum voltages, since the voltage across the discharging switches is divided between the switching elements of the series circuits.

The residual current detection means FE, by measuring the voltage between HV+, HV− on the one hand and on the other hand M, captures whether a potential shift arises due to a residual current RF, RF′. As a result, it can be determined whether a residual current RF, RF′ is present and from which HV potential this residual current emanates (or which faulty HV potential is the cause of the residual current). The residual current generally arises due to an insulation fault of the high-voltage electrical system HN with respect to the ground potential M and can therefore also be called insulation fault current.

With reference to the FIGURE, the insulation monitoring device IW of a charging-station high-voltage electrical system described here or a corresponding charging station can also be described: The connections 1, 2 are in this case a charging connection of the charging station or connections of the insulation monitoring device which are connected to DC charging connections of the charging station. The potentials HV+, − are the DC high-voltage potentials of the charging station or potentials of the monitoring device that are connected hereto (via connections HA1, HA2). A ground potential M of the charging station is connected to the potentials HV+, − of the charging station via charging-station discharging switches S1, S2. Discharging resistors R1, R2, in series with the switches S1, S2, reduce or limit the discharging current. In the event of an insulation fault being captured, only one of the switches is closed. The manner of operation of the charging-station-related components and embodiments is the same as that of the vehicle-related components and embodiments, for which reason the FIGURE can also be used for explaining the charging-station-related components. With regard to the charging-station-related components, reference is made to the properties, modes of operation and features of the vehicle-related components. On account of the comparable properties and features, the same reference signs are used to illustrate the equivalences between vehicle-related components and charging-station-related components.

1. A method for discharging a vehicle high-voltage electrical system, which is galvanically isolated from a ground potential, in the presence of a residual current, the method comprising:
determining whether a residual current flows between a first HV potential of the vehicle high-voltage electrical system and the ground potential or a residual current flows between a second HV potential of the vehicle high-voltage electrical system and the ground potential; and
discharging only that Cy capacitance which exists between the ground potential and that HV potential from which or to which the residual current flows, wherein the discharging is triggered by determining the existence of a residual current.

2. The method as claimed in claim 1, wherein discharging of that Cy capacitance which is connected between the ground potential and that HV potential which has no residual current flow is prevented.

3. The method as claimed in claim 1, wherein, after discharging the Cy capacitance which is connected to the HV potential linked to the residual current flow, the other Cy capacitance is discharged.

4. The method as claimed in claim 1, wherein, after discharging the Cy capacitance which is connected to the HV potential linked to the residual current flow, a high-voltage source of the vehicle high-voltage electrical system is disconnected.

5. The method as claimed in claim 1, wherein a fault signal is emitted if a residual current is determined.

6. The method as claimed in claim 1, wherein, after discharging the Cy capacitance which is connected to the HV potential linked to the residual current flow, a Cx capacitance which exists between the first HV potential and the second HV potential is discharged.

7. The method as claimed in claim 1, wherein the determining of whether a residual current flows between a first HV potential of the vehicle high-voltage electrical system and the ground potential or a residual current flows between a second HV potential of the vehicle high-voltage electrical system and the ground potential comprises: measuring an impedance across which the residual current flows, wherein furthermore the step of discharging the Cy capacitance is carried out only if this impedance lies in an impedance range which characterizes the impedance of a human body, wherein disconnection of a high-voltage source of the vehicle high-voltage electrical system and/or discharging of a Cx capacitance which exists between the first HV potential and the second HV potential is prevented.

8. The method as claimed in claim 1, wherein the determining of whether a residual current flows between a first HV potential of the vehicle high-voltage electrical system and the ground potential or a residual current flows between a second HV potential of the vehicle high-voltage electrical system and the ground potential comprises: measuring a rate of change of a voltage between ground and one of the HV potentials, wherein it is determined that a residual current exists if the absolute value of the rate of change lies above a limit which characterizes the maximum rate of change which occurs during an active insulation measurement.

9. An insulation monitoring device of a vehicle high-voltage electrical system, wherein the insulation monitoring device has a ground potential connection and a first and a second HV potential connection, wherein the insulation monitoring device comprises:
a residual current detection means which is designed to detect a first residual current between a first HV potential of the first HV potential connection and the ground potential of the ground potential connection, and a second residual current between a second HV potential of the second HV potential connection and the ground potential of the ground potential connection; and
a discharging circuit, wherein the residual current detection means is connected to the discharging circuit such that it can drive the latter, wherein the discharging circuit is configured to connect only the first HV potential connection to the ground potential connection in a controlled manner if the residual current detection means captures the first residual current, and to connect only the second HV potential connection to the ground potential connection if the residual current detection means captures the second residual current.

10. The insulation monitoring device as claimed in claim 9, wherein the discharging circuit has a first discharging switch between the first HV potential connection and the ground potential connection, and has a second discharging switch between the second HV potential connection and the ground potential connection, which discharging switches are configured to be closed only one at a time, and not simultaneously.

11. An on-board vehicle electrical system having an insulation monitoring device as claimed in claim 9 and having a ground potential and a vehicle high-voltage electrical system which is galvanically isolated from said ground potential and has a first HV potential and a second HV potential, wherein the first HV potential connection of the insulation monitoring device is connected to the first HV potential of the vehicle high-voltage electrical system, the second HV potential connection of the insulation monitoring device is connected to the second HV potential of the vehicle high-voltage electrical system, and the ground potential connection of the insulation monitoring device is connected to the ground potential of the on-board vehicle electrical system.

12. An insulation monitoring device of a charging-station high-voltage electrical system, wherein the insulation monitoring device has a ground potential connection and a first and a second HV potential connection, wherein the insulation monitoring device comprises:
a residual current detection means which is designed to detect a first residual current between a first HV potential of the first HV potential connection and the ground potential of the ground potential connection, and a second residual current between a second HV potential of the second HV potential connection and the ground potential of the ground potential connection; and
a discharging circuit, wherein the residual current detection means is connected to the discharging circuit such that it can drive the latter, wherein the discharging circuit is configured to connect only the first HV potential connection to the ground potential connection in a controlling manner if the residual current detection means measures the first residual current, and to connect only the second HV potential connection to the ground potential connection if the residual current detection means measures the second residual current.

13. The insulation monitoring device as claimed in claim 12, wherein the discharging circuit has a first discharging switch between the first HV potential connection and the ground potential connection, and has a second discharging switch between the second HV potential connection and the ground potential connection, which discharging switches are configured to be closed only one at a time, and not simultaneously.
